(19) United States
(12) Patent Application Publication
(10) Pub. No.: US 2025/0336739 A1
(43) Pub. Date: Oct. 30, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chao-Chiang PU, Taichung City (TW); Chi-Ching HO, Taichung City (TW); Yi-Min FU, Taichung City (TW); Yu-Po WANG, Taichung City (TW); Che-Yu LEE, Taichung City (TW)

(21) Appl. No.: 18/791,906

(22) Filed: Aug. 1, 2024

(30) Foreign Application Priority Data
Apr. 24, 2024 (TW) 113115300

(51) Int. Cl. H01L 23/18; H01L 21/56; H01L 23/00; H01L 23/31; H01L 23/498; H01L 25/10

(52) U.S. Cl. CPC H01L 23/18; H01L 21/563; H01L 21/568; H01L 23/3121; H01L 23/49811; H01L 24/16; H01L 24/32; H01L 24/73; H01L 25/105; H01L 2224/16225; H01L 2224/32225; H01L 2224/73204; H01L 2224/73253; H01L 2225/1041; H01L 2924/1815

(57) ABSTRACT

An electronic package and a manufacturing method thereof are provided. The electronic package at least includes an electronic element, a conductive pillar, a reinforcement member, an encapsulation layer and a redistribution layer. The conductive pillar and the reinforcement member are both disposed around the electronic element. The electronic element, the conductive pillar and the reinforcement member are encapsulating by the encapsulation layer. The redistribution layer is disposed on the same side of the electronic element, the conductive pillar, the reinforcement member and the encapsulation layer, and electrically connected to the electronic element and the conductive pillar. The reinforcement member has high hardness and a tunable coefficient of thermal expansion (CTE), which can enhance the strength and rigidity of the electronic package to reduce the warpage of the electronic package.

### BACKGROUND

### Cross-Reference to Related Applications

The present application is based upon and claims the right of priority to TW patent application No. 113115300, filed Apr. 24, 2024, the disclosure of which is hereby incorporated by reference herein in its entirety for all purposes.

### 1. Technical Field

The present disclosure relates to a package structure, and more particularly, to an electronic package with a reinforcement member and manufacturing method thereof.

### 2. Description of Related Art

FIG. 1 is a schematic cross-sectional view of a conventional semiconductor package 1.

As shown in FIG. 1, a semiconductor package 1 comprises a first insulating layer 111, a first semiconductor chip 12, an adhesive layer 121, conductive elements 123, a second insulating layer 124, conductive pillars 112, a first encapsulation colloid 113, a redistribution layer 13, a second semiconductor chip 14, first conductive bumps 142, a first underfill 143, a second encapsulation colloid 144, a under bump metallurgy 151, second conductive bumps 152, a second underfill 153, a package substrate 10, and conductors 103.

A plurality of electrode pads 122 are disposed on the active surface of the upper side of the first semiconductor chip 12. A plurality of the conductive elements 123 are bonded to the plurality of electrode pads 122. The second insulating layer 124 is disposed on the active surface of the respective first semiconductor chip 12, and disposed around the plurality of conductive elements 123. The first semiconductor chip 12 is bonded to the first insulating layer 111 with its non-active surface on the lower side through the adhesive layer 121. A plurality of conductive pillars 112 are disposed around the first semiconductor chip 12. The first encapsulation colloid 113 covers the plurality of conductive pillars 112, the first semiconductor chips 12, the adhesive layer 121, and the second insulating layer 124. The redistribution layer 13 is disposed on the upper side of the first semiconductor chips 12, the plurality of conductive elements 123, the second insulating layer 124, the plurality of conductive pillars 112, and the first encapsulation colloid 113.

The second semiconductor chips 14 has both the non-active surface on the upper side and the active surface on the lower side, and the active surface has a plurality of electrode pads 141 to be bonded to a plurality of first conductive bumps 142. The second semiconductor chip 14 is boned to the upper side of the redistribution layer 13 through the electrode pads 141 and the first conductive bumps 142 in a flip-chip manner. The first underfill 143 covers a plurality of first conductive bumps 142. The encapsulation layer 144 is disposed on the upper side of the redistribution layer 13 and covers the second semiconductor chip 14 and the first underfill 143.

The package substrate 10 is disposed on the lower side of the first insulating layer 111. In specific, the first insulating layer 111 and the structure thereon are bonded to the upper side of the package substrate 10 through the under bump metallurgy 151 and second conductive bumps 152. The under bump metallurgy 151 is partly disposed in the first insulating layer 111, and second conductive bumps 152 are bonded to the lower side of the under bump metallurgy 151 and the upper side of the package substrate 10. The second underfill 153 covers second conductive bumps 152. Conductors 103 are disposed on the lower side of the package substrate 10.

As the threshold of the semiconductor packaging technology gradually increases, the dimension of the semiconductor package increases accordingly. However, in this large package structure such as the semiconductor package 1, warpage problems have begun to occur, thus an effective solution is urgently needed.

### SUMMARY

In view of the aforementioned shortcomings of the prior art, the present disclosure provides an electronic package, the electronic package comprises: a first electronic element, a plurality of conductive pillars, at least a reinforcement member, an encapsulation layer, and a redistribution layer. The conductive pillars and the reinforcement member are both disposed around the electronic element. The electronic element, the conductive pillars, and the reinforcement member are encapsulated by the encapsulating layer. The redistribution layer is formed on the same side of the electronic element, the conductive pillars, the reinforcement member, and the encapsulation layer, and is electrically connected to the electronic element and the conductive pillars.

The present disclosure also provides a manufacturing method of an electronic package, the manufacturing method comprises: disposing a plurality of conductive pillars and at least a reinforcement member around a first electronic element; forming an encapsulation layer encapsulating the electronic element, the conductive pillars, and the reinforcement member; and forming a redistribution layer on the same side of the first electronic element, the conductive pillars, the reinforcement member, and the encapsulation layer, wherein the redistribution layer is electrically connected to the electronic element and the conductive pillars.

As can be seen from the above, the electronic package of the present disclosure comprises a reinforcement member. The hardness of the reinforcement member is higher than that of the encapsulation layer, and the reinforcement member has a tunable coefficient of thermal expansion (CTE), thus it can improve the strength and the rigidity of the structure of the electronic package to reduce the warpage of the electronic package, so as to facilitate the development of advanced packaging technology.

### BRIEF DESCRIPTION OF THE DRAWINGS

FIG. 1 is a schematic cross-sectional view of a conventional semiconductor package.

FIG. 2A to FIG. 2K are schematic cross-sectional views of a manufacturing method of an electronic package of an embodiment of the present disclosure.

FIG. 3A is a schematic cross-sectional view of a manufacturing method of an electronic package of another embodiment of the present disclosure.

FIG. 3B is a schematic cross-sectional view of a manufacturing method of an electronic package of a further embodiment of the present disclosure.

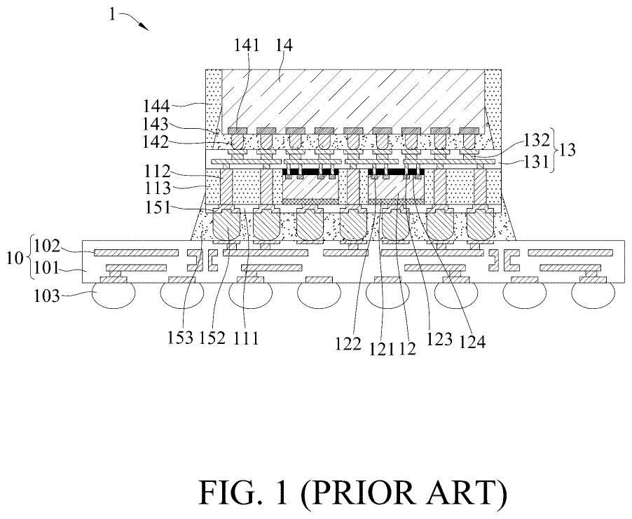

### DETAILED DESCRIPTION

The following describes the implementation of the present disclosure with examples. Those skilled in the art can easily understand other advantages and effects of the present disclosure from the contents disclosed in this specification.

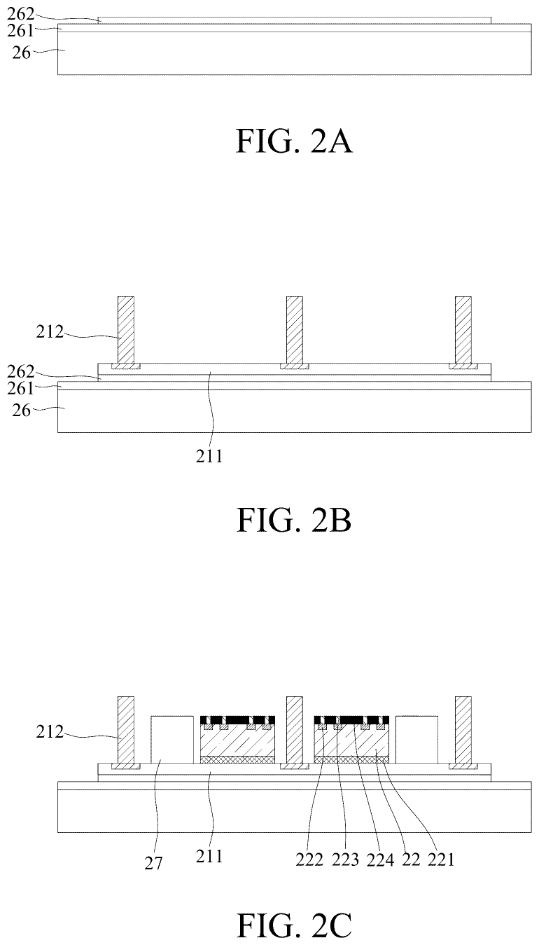

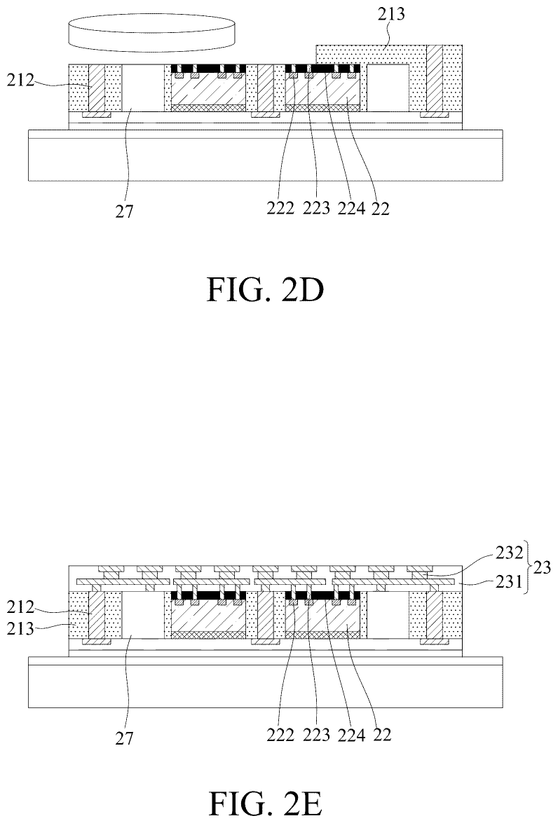

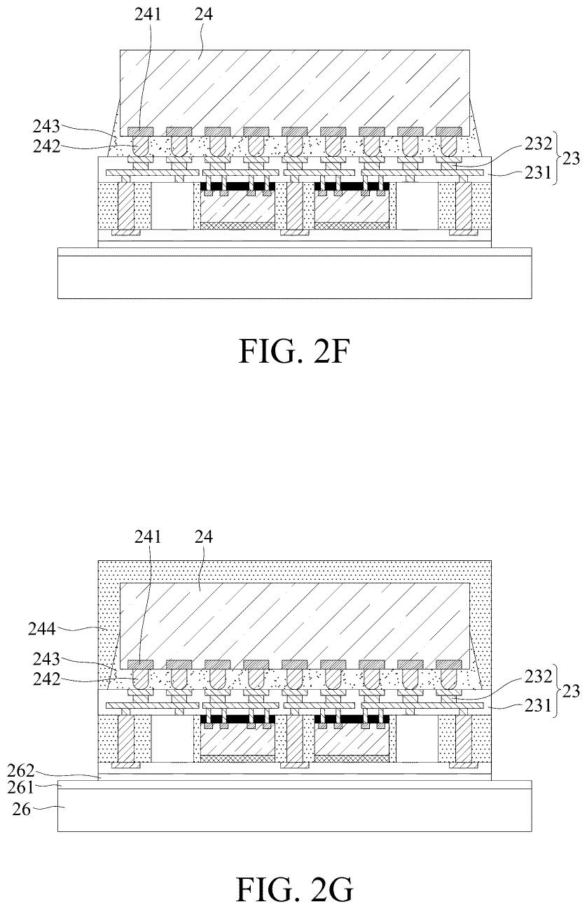

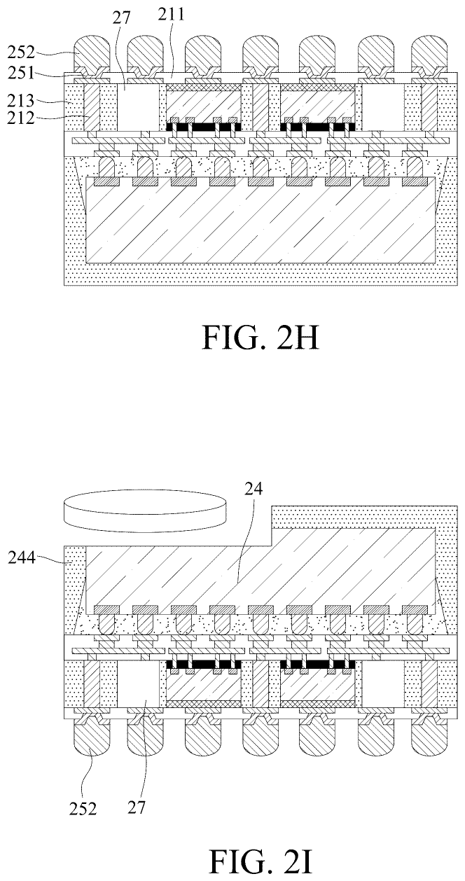

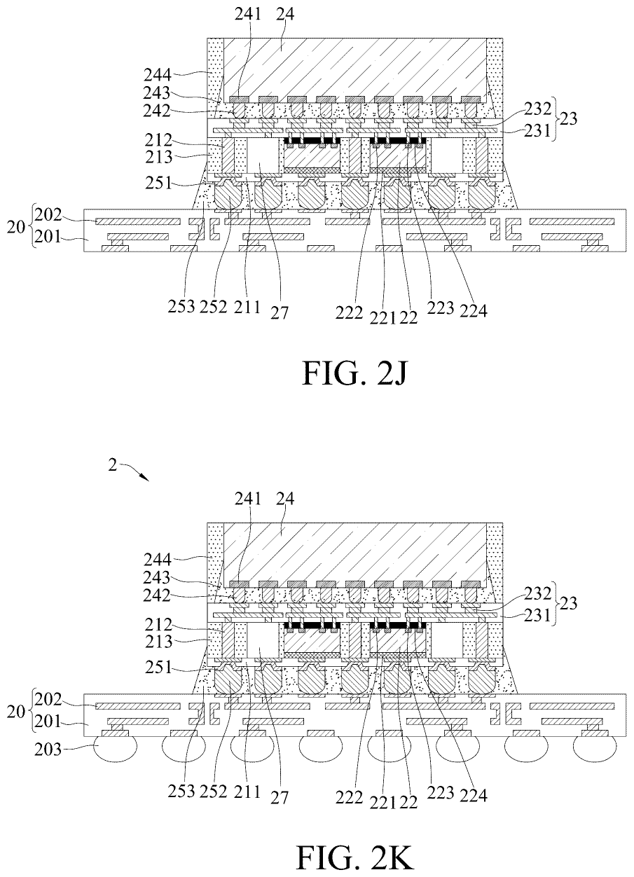

FIG. 2A to FIG. 2K are schematic cross-sectional views of a manufacturing method of an electronic package of an embodiment of the present disclosure.

First, as shown in FIG. 2A, a release layer 261 is formed on a first side of a carrier 26, then a base layer 262 is formed or disposed on a first side of the release layer 261.

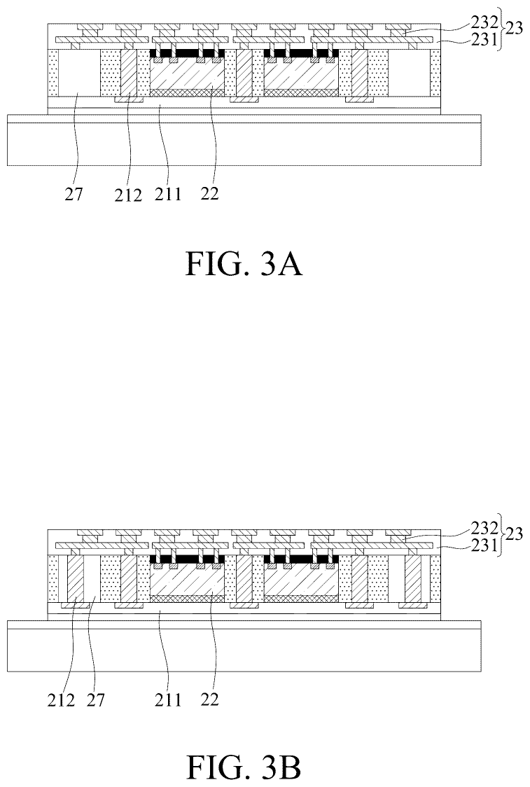

Elements such as the carrier 26, the release layer 261, and the base layer 262 shown in FIG. 2A all have a first side and a second side opposite to the first side. Besides, other elements also have a first side and a second side opposite to the first side as shown in FIGS. 2B-2K, 3A and 3B.

As shown in FIG. 2B, a first insulating layer 211 is formed on a first side of the base layer 262, and a plurality of conductive pillars 212 are disposed on the first side of the base layer 262. A lower end of each conductive pillar 212 is disposed in the first insulating layer 211, and the remaining portion of each conductive pillar 212 is disposed on the first side of the first insulating layer 211. The material forming the conductive pillar 212 is, for example, copper.

The material forming the first insulating layer 211 may be polybenzoxazole (PBO), polyimide (PI), prepreg (pp), or other dielectric materials.

As shown in FIG. 2C, at least a first electronic element 22 is disposed on the first insulating layer 211, and the plurality of conductive pillars 212 are disposed around the first electronic element 22. FIG. 2C shows a plurality of first electronic elements 22, wherein each first electronic element 22 is bonded to the first side of the first insulating layer 211 with an inactive surface on the second side thereof through an adhesive material 221 such as glue. A plurality of electrode pads 222 are disposed on the active surface on the first side of each first electronic element 22, a conductive element 223 is formed on the first side of each electrode pad 222, and a second insulating layer 224 is formed on the active surface of each first electronic element 22 and around the conductive element 223.

The material forming the conductive element 223 is, for example, copper, and the material forming the second insulating layer 224 may be polybenzoxazole (PBO), polyimide (PI), prepreg (pp), or other dielectric materials.

Each first electronic element 22 may be an active element, a passive element, or a combination thereof, and the active element is, for example, a semiconductor chip, and the passive element is, for example, a resistor, a capacitance, and an inductor.

In addition, at least a reinforcement member 27 is disposed around the first electronic element 22, wherein the reinforcement member 27 is disposed on the first side of the first insulating layer 211. The reinforcement member 27 may be a glass bulk, a metal bulk, or a dummy die.

As shown in FIG. 2D, a first encapsulation layer 213 is formed on the first side of the first insulating layer 211, allowing the first insulating layer 211 and the conductive pillar 212 as well as the reinforcement member 27, the adhesive layer 221, the first electronic element 22, the electrode pad 222, the conductive element 223, the second insulating layer 224 located on the first side of the first insulating layer 211 to be encapsulated by the first encapsulation layer 213.

The material forming the first encapsulation layer 213 is an insulating material such as polyimide (PI), epoxy encapsulation colloid, or encapsulation material. The first encapsulation layer 213 may be formed in a manner of molding, lamination, or coating.

Then, grinding the upper end of the first encapsulation layer 213 to expose the conductive pillar 212, the reinforcement member 27, the conductive element 223, and the second insulating layer 224.

As shown in FIG. 2E, a redistribution layer 23 is formed on the first side of the conductive pillar 212, the reinforcement member 27, the first electronic element 22, the conductive element 223, the second insulating layer 224, and the first encapsulation layer 213.

The redistribution layer 23 comprises at least an insulating layer 231 and at least a circuit layer 232 bonded to the insulating layer 231. For example, the material forming the circuit layer 232 is copper, and the material forming the insulating layer 231 may be the aforementioned polybenzoxazole (PBO), polyimide (PI), prepreg (pp), or other dielectric materials.

The circuit layer 232 of the redistribution layer 23 is electrically connected to the conductive pillar 212, and is electrically connected to each first electronic element 22 through the conductive element 223 and the electrode pad 222.

As shown in FIG. 2F, at least a second electronic element 24 is disposed on the first side of the redistribution layer 23. The second electronic element 24 may be an active element, a passive element, or a combination thereof, and the active element is, for example, a semiconductor chip, and the passive element is, for example, a resistor, a capacitance, and an inductor.

The second electronic element 24 has the inactive surface on the first side and the active surface on the second side. The active surface has a plurality of electrode pads 241 to be bonded to a plurality of first conductive bumps 242. Each first conductive bump 242 may be formed of solder material or a conductive metal material. The second semiconductor chip 24 is boned to the first side of the redistribution layer 23 through the electrode pads 241 and the first conductive bumps 242 of the active surface in a flip-chip manner to be electrically connected to the circuit layer 232 of the redistribution layer 23. For instance, a first underfill 243 can be used to encapsulate the plurality of first conductive bumps 242.

As shown in FIG. 2G, a second encapsulation layer 244 is formed on the first side of the redistribution layer 23, allowing the second electronic element 24 and the first underfill 243 to be encapsulated by the second encapsulation layer 244.

The material forming the second encapsulation layer 244 is an insulating material such as polyimide (PI), epoxy encapsulation colloid, or encapsulation material. The second encapsulation layer 244 may also be formed in a manner of molding, lamination, or coating.

As shown in FIG. 2H, the carrier 26, the release layer 261, and the base layer 262 shown in FIG. 2G are removed, and then turning over the remaining structure. Then, the under bump metallurgy (UBM) 251 is formed. The under bump metallurgy 251 is partially formed in the first insulating layer 211, and the under bump metallurgy 251 can be electrically connected to the conductive pillar 212.

Then, a plurality of second conductive bumps 252 are formed or disposed on the under bump metallurgy 251. Each second conductive bump 252 may be formed of solder material or a conductive metal material.

As shown in FIG. 2I, turning upside down the structure shown in FIG. 2H, and then grinding the upper end of the structure to expose the second electronic element 24.

As shown in FIG. 2J, the structure shown in FIG. 2I is bonded to the first side of a carrier structure 20 through the second conductive bumps 252, and that the conductive pillar 212 is electrically connected to the circuit layer 202 of the carrier structure 20 through the under bump metallurgy 251 and the second conductive bump 252. Additionally, the second underfill 253 can be used to encapsulate the second conductive bump 252.

The carrier structure 20 may be a package substrate or an interposer, which comprises at least an insulating layer 201 and at least a circuit layer 202 bonded to the at least an insulating layer 201. For instance, the material forming the circuit layer 202 is copper, and the material forming the insulating layer 201 may be the aforementioned polybenzoxazole (PBO), polyimide (PI), prepreg (pp), or other dielectric materials. It can be understood that the carrier structure 20 can also be other board material such as a lead frame, a wafer, or other boards with metal routing.

As shown in FIG. 2K, a plurality of conductors 203 are formed on the second side of the carrier structure 20, and that the conductors 203 are electrically connected to the circuit layer 202 of the carrier structure 20 to complete the electronic package 2.

Each conductor 203 is, for example, a conductive pillar or a conductive bump.

Through the aforementioned process, the electronic package 2 of the present disclosure comprises a first insulating layer 211, at least a first electronic element 22, an adhesive layer 221, a plurality of conductive elements 223, a second insulating layer 224, a plurality of conductive pillars 212, at least a reinforcement member 27, a first encapsulation layer 213, a redistribution layer 23, at least a second electronic element 24, a plurality of first conductive bumps 242, a first underfill 243, a second encapsulation layer 244, under bump metallurgy 251, a plurality of second conductive bumps 252, a second underfill 253, a carrier structure 20, and a plurality of conductors 203.

A plurality of electrode pads 222 are disposed on the active surface of the first side of the first electronic element 22. The plurality of conductive elements 223 are bonded to the plurality of electrode pads 222. The second insulating layer 224 is disposed on the active surface of the first electronic element and is disposed around the conductive element 223. The first electronic element 22 is bonded to the first side of the first insulating layer 211 with the inactive surface on its second side through an adhesive layer 221. The conductive pillar 212 and the reinforcement member 27 are disposed on the first side of the first insulating layer 211 and disposed around the first electronic element 22. The conductive pillar 212, the reinforcement member 27, the first electronic element 22, the adhesive layer 221, and the second insulating layer 224 are encapsulated by the first encapsulation layer 213. The redistribution layer 23 is disposed on the first side of the first electronic element 22, the conductive element 223, the second insulating layer 224, the conductive pillar 212, the reinforcement member 27, and the first encapsulation layer 213.

The second electronic element 24 has the inactive surface on the first side and the active surface on the second side, and the active surface has a plurality of electrode pads 241 to be bonded to a plurality of first conductive bumps 242. The second electronic element 24 is bonded to the first side of the redistribution layer 23 through the electrode pads 241 and the first conductive bumps 242 in a flip-chip manner. Theunderfill first conductive bumps 242 are encapsulated by the first underfill 243. The second encapsulation layer 244 is disposed on the first side of the redistribution layer 23 and encapsulating the second electronic element 24 and the first underfill 243.

The carrier structure 20 is disposed on the second side of the first insulating layer 211. In specific, the first insulating layer 211 and the structure thereon are bonded to the first side of the carrier substrate 20 through the under bump metallurgy 251 and second conductive bumps 252. The second underfill 253 covers second conductive bumps 252. The conductors 203 are disposed on the second side of the carrier substrate 20.

The conductive conductor 203 is electrically connected to the circuit layer 202 of the carrier structure 20, the second conductive bump 252, the under bump metallurgy 251, the conductive pillar 212, the circuit layer 232 of the redistribution layer 23, the conductive element 223, the electrode pad 222 of the first electronic element 22, the first conductive bump 242, and the electrode pad 241 of the second electronic element 24. Through the aforementioned electrical connection relationship, the conductor 203 can be electrically connected to the first electronic element 22 and the second electronic element 24.

In the electronic package 2 shown in FIG. 2K, the reinforcement member 27 is formed or disposed between the first electronic element 22 and the conductive pillar 212, but the present disclosure is not limited to as such.

For instance, FIG. 3A is a schematic cross-sectional view of a step in a manufacturing method of an electronic package 2 of another embodiment of the present disclosure, the step corresponds to the step shown in FIG. 2E. As shown in FIG. 3A, in this embodiment, the reinforcement member 27 is formed of disposed outside the first electronic element 22 and the conductive pillar 212, and that the conductive pillar 212 is disposed between the first electronic element 22 and the reinforcement member 27.

As another example, FIG. 3B is a schematic cross-sectional view of a step in a manufacturing method of an electronic package 2 of a further embodiment of the present disclosure, the step corresponds to the step shown in FIG. 2E. As shown in FIG. 3B, in this embodiment, the reinforcement member 27 is formed of disposed around the conductive pillar 212, allowing the reinforcement member 27 to be penetrated by the conductive pillar 212.

Since the electronic package 2 of the present disclosure comprises a reinforcement member 27, thus the volume of the first encapsulation layer 213 can be reduced to 30%. In addition, the hardness of the reinforcement member 27 is higher than that of the first encapsulation layer 213, and the reinforcement member has a tunable coefficient of thermal expansion (CTE), thus it can improve the strength and the rigidity of the package structure to reduce the warpage of the electronic package 2 such a large package structure, so as to facilitate the development of advanced packaging technology.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a first electronic element;
a plurality of conductive pillars disposed around the first electronic element;
at least a reinforcement member disposed around the first electronic element;
a first encapsulation layer for encapsulating the first electronic element, the conductive pillar, and the reinforcement member; and
a redistribution layer formed on a first side of the first electronic element, the conductive pillars, the reinforcement member, and the first encapsulation layer, wherein the redistribution layer is electrically connected to the first electronic element and the conductive pillars.

2. The electronic package of claim 1, wherein the reinforcement member is a glass bulk, a metal bulk, or a dummy die.

3. The electronic package of claim 1, wherein the reinforcement member is disposed between the first electronic element and the conductive pillars.

4. The electronic package of claim 1, wherein the reinforcement member is disposed outside the first electronic element and the conductive pillars.

5. The electronic package of claim 1, wherein the reinforcement member is penetrated by the conductive pillars.

6. The electronic package of claim 1, further comprising a first insulating layer formed on the first encapsulation layer, such that the first electronic element is bonded to the first insulating layer via an inactive surface of the first electronic element by an adhesive layer.

7. The electronic package of claim 1, further comprising a second electronic element disposed on a first side of the redistribution layer, and electrically connected to the redistribution layer.

8. The electronic package of claim 7, further comprising a second encapsulation layer formed on the first side of the redistribution layer and encapsulating the second electronic element.

9. The electronic package of claim 1, further comprising a carrier structure having a first side and a second side opposite to the first side for the first electronic element, the conductive pillars, the reinforcement member and the first encapsulation layer to be disposed on the first side of the carrier structure, and electrically connected to the redistribution layer through the conductive pillars.

10. The electronic package of claim 9, wherein the second side of the carrier structure is disposed with a plurality of conductors.

11. A method of manufacturing an electronic package, comprising:
disposing a plurality of conductive pillars and at least a reinforcement member around a first electronic element;
forming a first encapsulation layer for encapsulating the first electronic element, the conductive pillars, and the reinforcement member; and
forming a redistribution layer on a first side of the first electronic element, the conductive pillars, the reinforcement member, and the first encapsulation layer, wherein the redistribution layer is electrically connected to the first electronic element and the conductive pillars.

12. The method of claim 11, wherein the reinforcement member is a glass bulk, a metal bulk, or a dummy die.

13. The method of claim 11, wherein the reinforcement member is disposed between the first electronic element and the conductive pillars.

14. The method of claim 11, wherein the reinforcement member is disposed outside the first electronic element and the conductive pillars.

15. The method of claim 11, wherein the reinforcement member is configured to surround the conductive pillars in a manner that the reinforcement member is penetrated by the conductive pillars.

16. The method of claim 11, further comprising forming a first insulating layer before disposing the conductive pillars, wherein the conductive pillars are disposed on a first side of the first insulating layer, and the first electronic element is bonded to the first side of the first insulating layer via an inactive surface thereof by an adhesive layer, and the reinforcement member and the first encapsulation layer are disposed on the first side of the first insulation layer.

17. The method of claim 11, further comprising disposing a second electronic element on a first side of the redistribution layer, for the second electronic element to be electrically connected to the redistribution layer.

18. The method of claim 17, further comprising forming a second encapsulation layer on the first side of the redistribution layer, for the electronic element to be encapsulated by the second encapsulation layer.

19. The method of claim 11, further comprising bonding the electronic package comprising the first electronic element, the conductive pillars, the reinforcement member, the first encapsulation layer, and the redistribution layer to a first side of a carrier structure, wherein the conductive pillars are electrically connected to the redistribution layer.

20. The method of claim 19, further comprising disposing a plurality of conductors on a second side of the carrier structure, wherein the conductors are electrically connected to the carrier structure.
